(19) United States
(12) Patent Application Publication
(10) Pub. No.: US 2025/0023536 A1
(43) Pub. Date: Jan. 16, 2025

(54) N-PATH FILTER

(71) Applicant: Murata Manufacturing Co., Ltd., Nagaokakyo-shi (JP)

(72) Inventor: Hajime KANDO, Nagaokakyo-shi (JP)

(21) Appl. No.: 18/904,134

(22) Filed: Oct. 2, 2024

Related U.S. Application Data
(63) Continuation of application No. PCT/JP2023/012498, filed on Mar. 28, 2023.

(30) Foreign Application Priority Data
Apr. 8, 2022 (JP) 2022-064609

(51) Int. Cl. H03H 7/06; H03H 7/01

(52) U.S. Cl. CPC H03H 7/06; H03H 7/0138

(57) ABSTRACT

An N-path filter includes an N number of signal paths, where N is an integer of three or more, connected in parallel with one another between an input-output terminal and an input-output terminal. A signal path includes a switch that is connected to the input-output terminal and that modulates an input signal, a switch that is connected to the input-output terminal and that modulates the input signal with the same phase as the switch, and a base filter that is connected between the switch and the switch. The switches modulate the input signal with a phase that is one of phases of the signal paths defining one period and is different for each of the signal paths. Base filters are each a low pass filter including inductors.

### CROSS REFERENCE TO RELATED APPLICATIONS

This application is a Continuation application of PCT Application No. PCT/JP2023/012498, filed on Mar. 28, 2023, and claims the benefit of priority to Japanese Patent Application No. 2022-064609, filed on Apr. 8, 2022. The entire contents of each application are hereby incorporated herein by reference.

### BACKGROUND OF THE INVENTION

### 1. Field of the Invention

The present invention relates to N-path filters.

### 2. Description of the Related Art

Japanese Unexamined Patent Application Publication No. 6-237149 discloses a variable frequency N-path filter. The N-path filter includes an N number of base filters disposed between an input terminal and an output terminal and has a narrow-band filter characteristic achieved by switching between the N number of base filters in sequence by using switches connected to both ends of the base filters. Furthermore, “An Alternative Approach to the Realization of Network Transfer Functions: The N-Path Filter”, L. E. FRANKS and I. W. SANDBERG, THE BELL SYSTEM TECHNICAL JOURNAL, September 1960, p 1321-1350 discloses an N-path filter including an RC ladder low pass filter defined by a resistance element and a capacitor.

Although the N-path filters disclosed in Japanese Unexamined Patent Application Publication No. 6-237149 and “An Alternative Approach to the Realization of Network Transfer Functions: The N-Path Filter”, L. E. FRANKS and I. W. SANDBERG, THE BELL SYSTEM TECHNICAL JOURNAL, September 1960, p 1321-1350 provide a narrow-band variable frequency filter, it is difficult for the N-path filters to have a wide and low-loss bandpass characteristic.

### SUMMARY OF THE INVENTION

Example embodiments of the present invention provide N-path filters each with a wide and low-loss bandpass characteristic.

An N-path filter according to an example embodiment of the present invention includes a first input-output terminal and a second input-output terminal, and an N number of signal paths, where N is an integer of three or more, connected in parallel with one another between the first input-output terminal and the second input-output terminal. Each of the N number of signal paths includes a first modulator connected to the first input-output terminal to modulate an input signal input from the first input-output terminal or the second input-output terminal, a second modulator connected to the second input-output terminal to modulate the input signal with the same phase as the first modulator, and a base filter connected between the first modulator and the second modulator. The first modulator and the second modulator are configured to modulate the input signal with a phase that is one of phases of the N number of signal paths defining one period and is different for each of the signal paths. The base filter is a low pass filter including an inductor.

Example embodiments of the present invention provide N-path filters each with a wide and low-loss bandpass characteristic.

The above and other elements, features, steps, characteristics and advantages of the present invention will become more apparent from the following detailed description of the example embodiments with reference to the attached drawings.

### BRIEF DESCRIPTION OF THE DRAWINGS

FIG. 1 is a circuit configuration diagram of an N-path filter according to an example embodiment of the present invention.

FIG. 2 is a timing chart illustrating drive signals in an N-path filter according to an example embodiment of the present invention.

FIG. 3 is a diagram illustrating an example of a circuit configuration of a base filter according to an example embodiment of the present invention.

FIG. 4A is a graph representing a bandpass characteristic in the vicinity of a pass band of a single base filter according to an example embodiment of the present invention.

FIG. 4B is a graph representing a bandpass characteristic in a wide band including an attenuation band of a single base filter according to an example embodiment of the present invention.

FIG. 5A is a graph representing a bandpass characteristic in the vicinity of a pass band of an N-path filter according to an example embodiment of the present invention.

FIG. 5B is a graph representing a bandpass characteristic in a wide band including an attenuation band of an N-path filter according to an example embodiment of the present invention.

FIG. 6 is a diagram illustrating an example of a circuit configuration of a base filter according to a comparative example.

FIG. 7A is a graph representing a bandpass characteristic in the vicinity of a pass band of an N-path filter according to the comparative example.

FIG. 7B is a graph representing a bandpass characteristic in a wide band including an attenuation band of the N-path filter according to the comparative example.

FIG. 8 is a circuit configuration diagram of a radio-frequency module and a communication device according to an example embodiment of the present invention.

### DETAILED DESCRIPTION OF THE EXAMPLE EMBODIMENTS

Example embodiments of the present invention will be described in detail below with reference to the drawings. All of the example embodiments described below describe comprehensive or specific examples. Numerical values, shapes, materials, components, the arrangement and connection configuration of the components, and so forth that are described in the following example embodiments are merely examples and are not intended to limit the present invention. Of components in the following example embodiments, a component not described in an independent claim is described as an optional component. Furthermore, the sizes or size ratio of components illustrated in drawings are or is not necessarily exact.

Furthermore, in the following example embodiments, unless otherwise specified, a pass band of a filter is defined as a frequency band between two frequencies at a value about 3 dB larger than a minimum value of insertion loss in the pass band.

Furthermore, in the following example embodiments, “signal path” refers to a transmission line defined by a line through which a radio-frequency signal propagates, a circuit element and an electrode connected directly to the line, a terminal connected directly to the line or the electrode, and so forth.

Furthermore, in the following example embodiments, when an element is referred to as being “connected” to another element, the element can not only be directly connected to the other element by using a connection terminal and/or a line conductor, but also electrically via another circuit element. Additionally, when an element is referred to as being “connected between A and B”, the element is connected to A and B on a path connecting A and B.

### EXAMPLE EMBODIMENT

### 1.1 Circuit Configuration of N-Path Filter 1

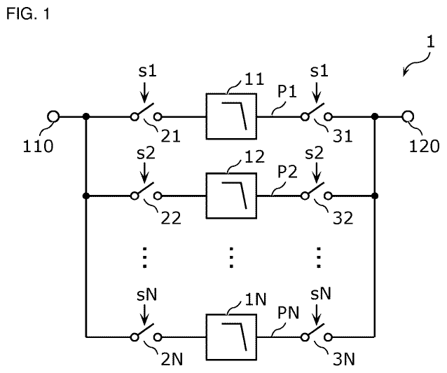

FIG. 1 is a circuit configuration diagram of an N-path filter 1 according to an example embodiment of the present invention. As illustrated in FIG. 1, the N-path filter 1 includes, for example, base filters 11 to 1N, where N is an integer of three or more, switches 21 to 2N, where N is an integer of three or more, switches 31 to 3N, where N is an integer of three or more, and input-output terminals 110 and 120.

The switch 21 is an example of a first switch and is connected to the input-output terminal 110 and the base filter 11. When the switch 21 performs on/off switching operation in accordance with a drive signal s1 based on a drive frequency fp, connection and disconnection between the input-output terminal 110 and the base filter 11 are switched.

The switch 31 is an example of a second switch and is connected to the input-output terminal 120 and the base filter 11. When the switch 31 performs on/off switching operation at the same time as the switch 21 in accordance with the drive signal s1, connection and disconnection between the input-output terminal 120 and the base filter 11 are switched.

The switch 22 is an example of the first switch and is connected to the input-output terminal 110 and the base filter 12. When the switch 22 performs on/off switching operation in accordance with a drive signal s2 based on the drive frequency fp, connection and disconnection between the input-output terminal 110 and the base filter 12 are switched.

The switch 32 is an example of the second switch and is connected to the input-output terminal 120 and the base filter 12. When the switch 32 performs on/off switching operation at the same time as the switch 22 in accordance with the drive signal s2, connection and disconnection between the input-output terminal 120 and the base filter 12 are switched.

The switch 2N is an example of the first switch and is connected to the input-output terminal 110 and the base filter 1N. When the switch 2N performs on/off switching operation in accordance with a drive signal sN based on the drive frequency fp, connection and disconnection between the input-output terminal 110 and the base filter 1N are switched.

The switch 3N is an example of the second switch and is connected to the input-output terminal 120 and the base filter 1N. When the switch 3N performs on/off switching operation at the same time as the switch 2N in accordance with the drive signal sN, connection and disconnection between the input-output terminal 120 and the base filter 1N are switched.

The base filter 11 and the switches 21 and 31 define a signal path P1. The base filter 12 and the switches 22 and 32 define a signal path P2. The base filter 1N, and the switches 2N and 3N define a signal path PN, where N is an integer of three or more.

The N-path filter 1 includes an N number of signal paths including the signal paths P1, P2, and PN, and the signal paths P1 to PN are connected in parallel with one another between the input-output terminal 110 and the input-output terminal 120.

The base filter 11 is a low pass filter connected between the switches 21 and 31 and including an inductor. The base filter 12 is a low pass filter connected between the switches 22 and 32 and including an inductor. The base filter 1N is a low pass filter connected between the switches 2N and 3N and including an inductor. A circuit configuration of the base filters 11 to 1N will be described in detail with reference to FIG. 3.

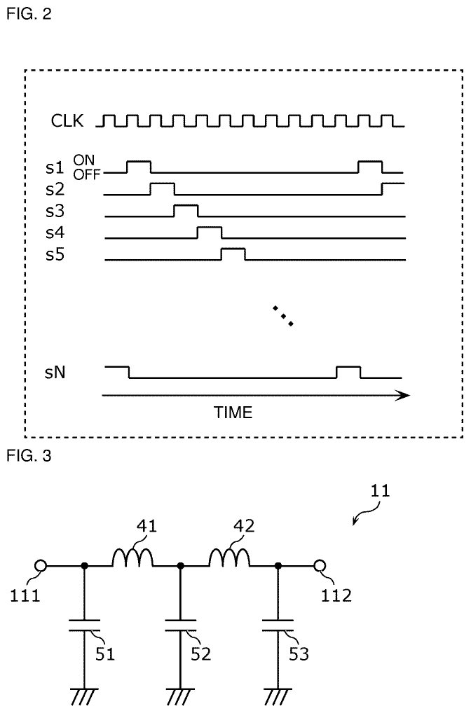

FIG. 2 is a timing chart illustrating drive signals in the N-path filter 1 according to the present example embodiment. FIG. 2 illustrates examples of the drive signals s1 to sN supplied to the switches 21 to 2N and the switches 31 to 3N. As illustrated in FIG. 2, the drive signals s1 to sN are generated in accordance with a clock signal CLK (the drive frequency fp). More specifically, when a period of the drive signals s1 to sN is defined as T, each of the drive signals s1 to sN is in an ON state only for a period of T/N, and the drive signals s1 to SN sequentially enter the ON state only after a delay of T/N. Thus, the switches 21 to 2N enter an ON state at a different point in time for each signal path in the period T. Furthermore, the switches 31 to 3N enter an ON state at a different point in time for each signal path in the period T. That is, the base filters 11 to 1N are connected to the input-output terminals 110 and 120 at a different point in time for each signal path in the period T.

The above-described configuration allows the N-path filter 1 to define and function as a band pass filter having a center frequency that is an on/off frequency of the switches 21 to 2N and the switches 31 to 3N (the drive frequency fp of the clock signal CLK) and having a pass band that is twice a pass band of the base filters 11 to 1N.

Furthermore, when the on/off frequency of the switches 21 to 2N and the switches 31 to 3N (the drive frequency fp) is changed, a pass band and an attenuation band of the N-path filter 1 can be varied.

Operation of the N-path filter 1 according to the present example embodiment is not limited to the operation based on the drive signals s1 to sN illustrated in FIG. 2. Each of the drive signals s1 to sN does not have to be in the ON state only for the period of T/N and may be in the ON state for a period shorter than T/N or a period longer than T/N. That is, periods for which the respective drive signals s1 to sN are in the ON state do not have to be strictly continuous and may be spaced slightly apart. Furthermore, the periods (lengths) for which the respective drive signals s1 to sN are in the ON state do not have to be the same and may be different.

In the above-described configuration of the N-path filter 1, since the base filters 11 to 1N are low pass filters including an inductor, a variable frequency filter can be implemented that has a wide and flat pass band in a region at the on/off frequency of the switches 21 to 2N and the switches 31 to 3N (the drive frequency fp).

In the N-path filter 1 according to the present example embodiment, each of the switches 21 to 2N only has to be a first modulator that modulates an input signal input from the input-output terminal 110 or 120. Furthermore, each of the switches 31 to 3N only has to be a second modulator that modulates an input signal input from the input-output terminal 110 or 120 with the same phase as the first modulator. Specifically, each of the first modulator and the second modulator modulates an input signal input from the input-output terminal 110 or 120 with a phase that is one of phases of the N number of signal paths forming one period and is different for each signal path. Although each of the switches 21 to 2N is an example of the first modulator and each of the switches 31 to 3N is an example of the second modulator, examples of the first modulator and the second modulator include mixers in addition to the switches 21 to 2N and the switches 31 to 3N.

Thus, since the base filters 11 to 1N are low pass filters including an inductor, a variable frequency filter can be provided that has a wide and flat pass band in a drive frequency region of the modulators.

### 1.2 Circuit Configuration and Bandpass Characteristic of Base Filters 11 to 1N

FIG. 3 is a diagram illustrating an example of the circuit configuration of the base filters 11 to 1N according to the present example embodiment. FIG. 3 illustrates, of the base filters 11 to 1N, an example of a circuit configuration of the base filter 11. Circuit configurations of the base filters 12 to 1N are preferably the same or substantially the same as the circuit configuration of the base filter 11 illustrated in FIG. 3.

As illustrated in FIG. 3, the base filter 11 includes inductors 41 and 42, and capacitors 51, 52, and 53. The inductors 41 and 42 are connected in series between a terminal 111 and a terminal 112. The capacitor 51 is connected between a node on a path connecting the terminal 111 and the inductor 41 and a ground. The capacitor 52 is connected between a node on a path connecting the inductor 41 and the inductor 42 and the ground. The capacitor 53 is connected between a node on a path connecting the terminal 112 and the inductor 42 and the ground. In the above-described connection configuration, the base filter 11 illustrated in FIG. 3 is, for example, a Butterworth filter, more specifically, a CLC 5-stage low pass filter.

Inductance values of both the inductors 41 and 42 are preferably, for example, about 1.03 pH, capacitance values of both the capacitors 51 and 53 are preferably, for example, about 2.46 pF, and a capacitance value of the capacitor 52 is preferably, for example, about 7.96 pF.

The inductors 41 and 42 are preferably, for example, surface-mount inductors, or inductors made of a spiral or meandering planar coil defined in a multilayer substrate and are not defined by parasitic inductance components of a circuit element and a line.

Furthermore, the base filters 11 to 1N may include a resistance element.

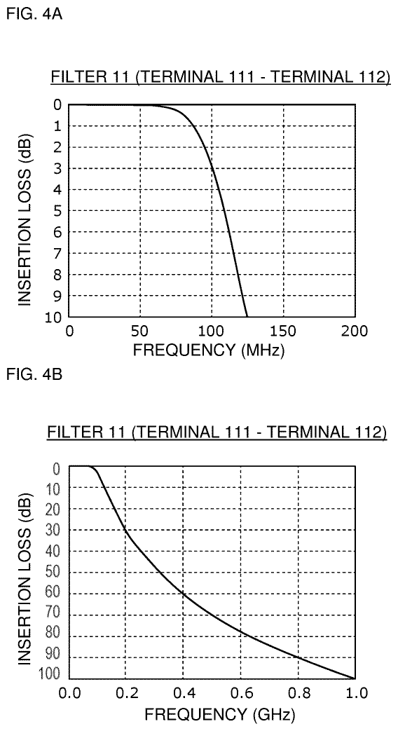

FIG. 4A is a graph representing a bandpass characteristic in the vicinity (for example, DC—about 200 MHz) of a pass band of the single base filter 11 according to the example embodiment. Furthermore, FIG. 4B is a graph representing a bandpass characteristic in a wide band (for example, DC—about 1 GHz) including an attenuation band of the single base filter 11 according to the example embodiment. As illustrated in FIG. 4A, in the bandpass characteristic of the base filter 11, a 3 dB-cutoff frequency is about 100 MHz, for example. Furthermore, for example, a ripple (a difference between a maximum insertion loss and a minimum insertion loss) in a range from DC to about 87 MHz is not more than about 1 dB, and a flat pass band is provided.

Furthermore, for use in a radio-frequency front-end circuit that transmits frequency bands, for example, for a Long Term Evolution (LTE) system, a 5th Generation (5G)-New Radio (NR) system, and a Wireless Local Area Network (WLAN) system that are predefined, for example, by the 3rd Generation Partnership Project (3GPP) (registered trademark), terminal impedances of the terminals 111 and 112 are designed to be, for example, about 400Ω (N=8).

In addition to the Butterworth filter illustrated in FIG. 3, the base filters 11 to 1N may be low pass filters, such as, for example, Bessel, Chebyshev, or elliptic low pass filters including an inductor in response to specifications demanded of a bandpass characteristic of the N-path filter 1.

Furthermore, it is preferable that each of the base filters 11 to 1N is defined by only a passive element.

Thus, active elements, such as, for example, an operational amplifier, a transistor, and a diode, are not included in the base filters 11 to 1N, making it possible to reduce signal distortion that occurs in an active element (a nonlinear element).

### 1.3 Bandpass Characteristic of N-Path Filter 1

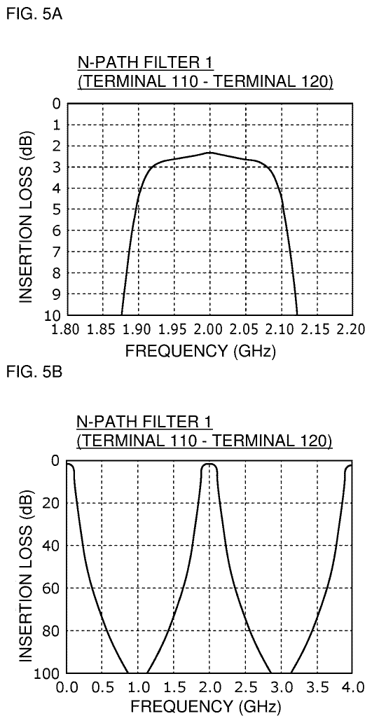

FIG. 5A is a graph representing a bandpass characteristic in the vicinity (for example, about 1.8 GHZ-about 2.2 GHz) of the pass band of the N-path filter 1 according to the present example embodiment. Furthermore, FIG. 5B is a graph representing a bandpass characteristic in a wide band (for example, DC—about 4 GHZ) including the attenuation band of the N-path filter 1 according to the present example embodiment. Incidentally, FIGS. 5A and 5B illustrate the bandpass characteristic of the N-path filter 1 exhibited when the circuit configuration illustrated in FIG. 3 is used as the circuit configuration of the base filters 11 to 1N and the on/off frequency of the switches 21 to 2N and the switches 31 to 3N (the drive frequency fp) is, for example, about 2 GHz under the condition of N=8.

Terminal impedances of the respective base filters 11 to 1N are, for example, about 400Ω, and thus terminal impedances of the input-output terminals 110 and 120 of the N-path filter 1 are, for example, about 50Ω. Furthermore, an on resistance of each of the switches 21 to 2N and the switches 31 to 3N is, for example, about 0.1Ω, and an off resistance is, for example, about 1 GΩ.

As illustrated in FIG. 5A, a pass band width in which a ripple (a difference between a maximum insertion loss and a minimum insertion loss) is, for example, not more than about 1 dB is about 176 MHz with a center frequency of about 2 GHZ, achieving a wide band. Furthermore, for example, a pass band (a difference between two frequencies at a value about 3 dB larger than the minimum insertion loss) with respect to the center frequency is about 10% and is not less than about 0.1%. Furthermore, the steepness of the transition between the pass band and the attenuation band can be increased.

In a case where the pass band of the N-path filter 1 is used so that the pass band includes frequency bands, for example, for an LTE system, a 5G-NR system, and a WLAN system, it is desirable that the pass band with respect to the center frequency be not less than 1%.

This allows the N-path filter 1 to be used in mobile phone systems that transmit signals in wide bands, such as LTE bands, Sub-6 (below 6 GHZ) bands, for example, and millimeter-wave bands (28 GHz band, 38 GHz band, for example).

In the N-path filter 1 according to the present example embodiment, when terminal impedances of the input-output terminals 110 and 120 are Z₀ and input-output impedances of the base filters 11 to 1N are Zb, it is preferable that a reflection coefficient (Zb−N×Z₀)/(Zb+N×Z₀) satisfy the relationship of Expression 1.

$$( Zb - N \times {Z}_{0} ) / ( Zb + N \times {Z}_{0} ) < 0.316 \qquad ( Expression 1 )$$

This allows return losses at the input-output terminals 110 and 120 to be less than about 10 dB, and thus losses due to mismatching with an external connection circuit connected to the input-output terminal 110 or 120 can be reduced. Thus, the N-path filter 1 can be used in a radio-frequency front-end circuit that transmits a radio-frequency signal with low loss.

In the N-path filter 1 according to the present example embodiment, the terminal impedances of the terminals 111 and 112 of the base filters 11 to 1N are designed to be, for example, about 400Ω, and the reflection coefficient is ideally 0 when Z₀=50Ω, Zb=400Ω, and N=8 are substituted in Expression 1.

Furthermore, in the N-path filter 1, each of the switches 21 to 2N and the switches 31 to 3N may include a semiconductor element. In this case, it is preferable that, of circuit elements (inductors and capacitors) included in each of the base filters 11 to 1N, a circuit element connected closest to at least one of any of the switches 21 to 2N and any of the switches 31 to 3N be a capacitor (a so-called shunt capacitor) connected between a path connecting the input-output terminals 110 and 120 and the ground. In the present example embodiment, the capacitors 51 and 53 correspond to a circuit element connected closest to at least one of any of the switches 21 to 2N and any of the switches 31 to 3N.

This allows a capacitor closest to any of the switches 21 to 2N or any of the switches 31 to 3N and the parasitic capacitance of the above-described semiconductor switch to be combined, and thus the base filters 11 to 1N can be provided as low pass filters in which attenuation characteristics are designed with high accuracy. Hence, a high-accuracy bandpass characteristic of the N-path filter 1 can be obtained.

### 1.4 Bandpass Characteristic of N-Path Filter According to Comparative Example

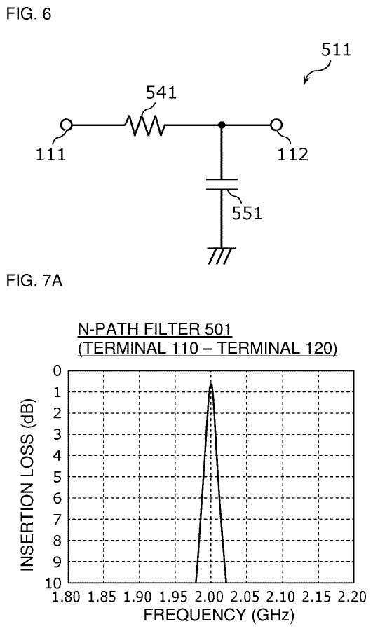

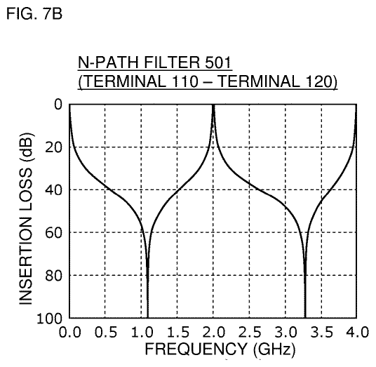

FIG. 6 is a diagram illustrating an example of a circuit configuration of a base filter 511 according to a comparative example. Furthermore, FIG. 7A is a graph representing a bandpass characteristic in the vicinity (about 1.8 GHZ-about 2.2 GHZ) of a pass band of an N-path filter 501 according to the comparative example. Furthermore, FIG. 7B is a graph representing a bandpass characteristic in a wide band (DC—about 4 GHZ) including an attenuation band of the N-path filter 501 according to the comparative example.

The N-path filter 501 according to the comparative example is an existing N-path filter and has a configuration in which an N number of signal paths that include two switches and the base filter 511 connected between the two switches are connected in parallel.

As illustrated in FIG. 6, the base filter 511 preferably includes a resistance element 541, and a capacitor 551. The resistance element 541 is connected between the terminal 111 and the terminal 112. The capacitor 551 is connected between a node on a path connecting the terminal 112 and the resistance element 541 and the ground. In the above-described connection configuration, the base filter 511 illustrated in FIG. 6 is an RC single-stage low pass filter. A resistance value of the resistance element 541 is preferably, for example, about 1Ω, and a capacitance value of the capacitor 551 is preferably, for example, about 1 nF.

FIGS. 7A and 7B illustrate a bandpass characteristic of the N-path filter 501 exhibited when the circuit configuration illustrated in FIG. 6 is used as the base filter 511 and an on/off frequency of each switch (a drive frequency fp) is about 2 GHZ under the condition of N=8. Furthermore, an on resistance of the switch is about 0.1Ω, and an off resistance is about 1 GO.

As illustrated in FIG. 7A, a pass band width in which a ripple (a difference between a maximum insertion loss and a minimum insertion loss) is not more than about 1 dB is about 7.9 MHz with a center frequency of about 2 GHZ, resulting in a narrow band. Furthermore, a pass band (a difference between two frequencies at a value about 3 dB larger than the minimum insertion loss) with respect to the center frequency is not more than about 0.8%.

The base filter 511 illustrated in FIG. 6 has a bandpass characteristic in which steep attenuation occurs from the vicinity of DC. For this reason, the bandpass characteristic of the N-path filter 501 using the base filter 511 exhibits unimodality as illustrated in FIG. 7A. On the other hand, to increase the bandwidth of the N-path filter 501 by using the base filter 511, it can be considered that the capacitance value of the capacitor 551 is reduced. In this case, however, the steepness of the transition from the pass band to the attenuation band deteriorates. Furthermore, when the resistance value of the resistance element 541 is increased to increase the bandwidth, the insertion loss in the pass band increases. That is, when an RC filter is used as the base filter 511, the bandpass characteristic exhibits unimodality, and it is difficult to obtain a low-loss and wide bandpass characteristic.

In a case where the N-path filter 501 according to the comparative example is used in a baseband signal processing circuit, the baseband signal processing circuit has to be reduced in size as an integrated circuit, and thus it is difficult to use an inductor that is larger in size in a baseband frequency band. For this reason, an RC filter is used as a base filter of an N-path filter used in the baseband signal processing circuit. However, in a case where the RC filter is built in an integrated circuit for baseband signal processing, a terminal impedance is set to be high, whereas it is difficult to design the terminal impedance to be near about 50Ω that is a reference impedance of a radio-frequency front-end circuit.

On the other hand, in the N-path filter 1 according to the present example embodiment, since the base filters 11 to 1N are low pass filters including an inductor, a variable frequency filter can be implemented that has a wide and flat pass band in a region at the on/off frequency of the switches 21 to 2N and the switches 31 to 3N (the drive frequency fp). Furthermore, in frequency bands, for example, for an LTE system, a 5G-NR system, and a WLAN system that are predefined, for example, by the 3GPP (registered trademark), the inductor can be reduced in size. Furthermore, to use the N-path filter 1 in a radio-frequency front-end circuit that transmits the above-described frequency bands, for example, a terminal impedance of the terminal 111 can be designed to be about 25Ω to about 100Ω, and a terminal impedance of the terminal 112 can be designed to be about 10Ω to about 400Ω.

### 1.5 Circuit Configuration of Radio-Frequency Module 5 and Communication Device 10 According to Embodiment

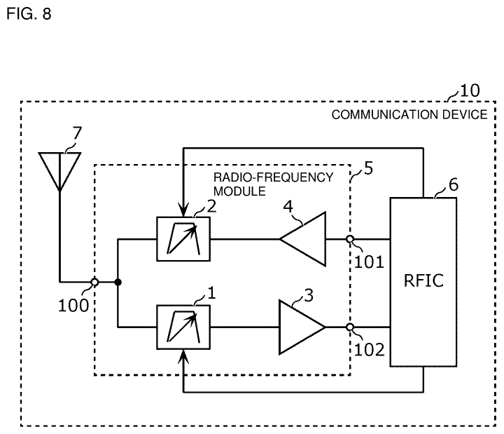

FIG. 8 is a circuit configuration diagram of a radio-frequency module 5 and a communication device 10 according to the example embodiment. As illustrated in FIG. 8, the communication device 10 includes the radio-frequency module 5, an RF signal processing circuit (RFIC) 6, and an antenna 7.

The radio-frequency module 5 transmits a radio-frequency signal between the antenna 7 and the RFIC 6. The antenna 7 is connected to an antenna connection terminal 100 of the radio-frequency module 5, transmits a radio-frequency signal output from the radio-frequency module 5, and also receives a radio-frequency signal from the outside and outputs the radio-frequency signal to the radio-frequency module 5.

The RFIC 6 is an example of a signal processing circuit that processes a radio-frequency signal. Specifically, the RFIC 6 performs, for example, through down-conversion, signal processing on a radio-frequency reception signal input through a reception path of the radio-frequency module 5 and outputs a reception signal generated through the signal processing to a baseband signal processing circuit (BBIC, which is not illustrated). Furthermore, the RFIC 6 performs, for example, through up-conversion, signal processing on a transmission signal input from the BBIC and outputs a radio-frequency transmission signal generated through the signal processing to a transmission path of the radio-frequency module 5. Furthermore, the RFIC 6 includes a controller that controls, for example, N-path filters 1 and 2 and amplifiers that are included in the radio-frequency module 5. Incidentally, some or all of functions of the RFIC 6 as the controller may be implemented outside the RFIC 6 and may be implemented, for example, in the BBIC or the radio-frequency module 5.

In the communication device 10 according to the present example embodiment, the antenna 7 is not an indispensable component.

Next, a circuit configuration of the radio-frequency module 5 will be described. As illustrated in FIG. 8, the radio-frequency module 5 includes the N-path filters 1 and 2, a power amplifier 4, a low noise amplifier 3, the antenna connection terminal 100, a radio-frequency input terminal 101, and a radio-frequency output terminal 102.

The antenna connection terminal 100 is connected to the antenna 7. The radio-frequency input terminal 101 is connected to the RFIC 6 and is a terminal to receive a radio-frequency transmission signal from the RFIC 6. The radio-frequency output terminal 102 is connected to the RFIC 6 and is a terminal for outputting a radio-frequency reception signal to the RFIC 6.

The N-path filter 1 is preferably a filter used for reception connected between the antenna connection terminal 100 and the low noise amplifier 3. In the N-path filter 1, a pass band and an attenuation band can be varied in accordance with drive signals s1 to sN output from the RFIC 6. This allows the N-path filter 1 to selectively pass radio-frequency signals in a plurality of bands.

The N-path filter 2 is preferably a filter used for transmission connected between the antenna connection terminal 100 and the power amplifier 4. In the N-path filter 2, a pass band and an attenuation band can be varied in accordance with drive signals s1 to sN output from the RFIC 6. This allows the N-path filter 2 to selectively pass radio-frequency signals in a plurality of bands.

A drive circuit that outputs the drive signals s1 to sN may be included in the controller of the RFIC 6 or may be included in the radio-frequency module 5. Alternatively, the drive circuit may be placed as a semiconductor Integrated Circuit (IC) separately from the radio-frequency module 5 and the RFIC 6.

The low noise amplifier 3 is connected between the N-path filter 1 and the radio-frequency output terminal 102 and amplifies a reception signal input from the antenna connection terminal 100.

The power amplifier 4 is connected between the N-path filter 2 and the radio-frequency input terminal 101 and amplifies a transmission signal input from the radio-frequency input terminal 101.

In the above-described configuration, filters corresponding to a respective plurality of wide bands do not have to be provided, and only one N-path filter corresponding to the plurality of bands has to be provided, thus enabling reductions in the sizes of the radio-frequency module 5 and the communication device 10.

The radio-frequency module 5 and the communication device 10 may include, in addition to circuit elements illustrated in FIG. 8, an impedance matching element, and a switch, for example.

Furthermore, the radio-frequency module 5 may include a plurality of power amplifiers, and a switch that switches between connections of any of the plurality of power amplifiers and the N-path filter 2. Furthermore, the radio-frequency module 5 may include a plurality of low noise amplifiers, and a switch that switches between connections of any of the plurality of low noise amplifiers and the N-path filter 1.

### Advantageous Effects

As described above, the N-path filter 1 according to the example embodiment includes the input-output terminals 110 and 120, and an N number of signal paths P1 to PN, where N is an integer of three or more, connected in parallel with one another between the input-output terminal 110 and the input-output terminal 120. The signal path PN includes the switch 2N that is connected to the input-output terminal 110 and that modulates an input signal input from the input-output terminal 110 or 120, the switch 3N that is connected to the input-output terminal 120 and that modulates the input signal with the same phase as the switch 2N, and the base filter 1N that is connected between the switch 2N and the switch 3N. The switch 2N and the switch 3N modulate the input signal with a phase that is one of phases of the signal paths P1 to PN forming one period and is different for each of the signal paths. Each of the base filters 11 to 1N is a low pass filter including the inductors 41 and 42.

Thus, since the base filters 11 to 1N are low pass filters including an inductor, a variable frequency filter can be implemented that has a wide and flat pass band in a region at the on/off frequency of the switches 21 to 2N and the switches 31 to 3N.

Furthermore, for example, in the N-path filter 1, the switch 2N may switch between connection and disconnection between the input-output terminal 110 and the base filter 1N in accordance with a drive signal, and the switch 3N may switch between connection and disconnection between the input-output terminal 120 and the base filter 1N at the same time as the switch 2N in accordance with the above-described drive signal.

This allows the N-path filter 1 to function as a band pass filter having a center frequency that is an on/off frequency of the switch 2N and the switch 3N and having a pass band that is twice the pass band of the base filter 1N.

Furthermore, for example, in the N-path filter 1, each of the switches 21 to 2N and the switches 31 to 3N may preferably include a semiconductor element. Of circuit elements included in each of the base filters 11 to 1N, a circuit element connected closest to at least one of any of the switches 21 to 2N and any of the switches 31 to 3N may be a capacitor connected between a path connecting the input-output terminals 110 and 120 and the ground.

This allows a capacitor closest to any of the switches 21 to 2N or any of the switches 31 to 3N and the parasitic capacitance of the above-described semiconductor switch to be combined, and thus the base filters 11 to 1N can be implemented as low pass filters in which attenuation characteristics are produced with high accuracy. Thus, a high-accuracy bandpass characteristic of the N-path filter 1 can be obtained.

Furthermore, for example, in the N-path filter 1, each of the base filters 11 to 1N may be defined by only a passive element.

Thus, active elements, such as an operational amplifier, a transistor, and a diode, are not included in the base filters 11 to 1N, making it possible to reduce signal distortion that occurs in an active element (a nonlinear element).

Furthermore, for example, when a terminal impedance of the N-path filter 1 is Z₀ and an input-output impedance of each of the base filters 11 to 1N is Zb, the relationship of (Zb−N×Z₀)/(Zb+N×Z₀)<0.316 may be satisfied.

This allows return losses at the input-output terminals 110 and 120 to be less than about 10 dB, and thus losses due to mismatching with an external connection circuit connected to the input-output terminal 110 or 120 can be reduced. Thus, the N-path filter 1 can be used in a radio-frequency front-end circuit that transmits a radio-frequency signal with low loss.

Furthermore, for example, a band width ratio of the N-path filter 1 may be more than about 0.1%.

This allows the N-path filter 1 to be used in mobile phone systems that transmit signals in wide bands, such as, for example, LTE bands, Sub-6 (below 6 GHZ) bands, and millimeter-wave bands (28 GHz band, 38 GHz band, for example).

### Other Example Embodiments

Although an N-path filter according to the present invention has been described above with an example embodiment, the present invention is not limited to the above-described example embodiment. The present invention also encompasses modifications obtained by making various modifications conceived by a person skilled in the art to the above-described example embodiment within the scope of the gist of the present invention, and various devices including the N-path filter 1 according to the present invention.

Furthermore, for example, in the N-path filter 1 according to the above-described example embodiment, matching elements, such as an inductor and a capacitor, and a switch circuit may be connected between components.

### INDUSTRIAL APPLICABILITY

Example embodiments of the present invention can be widely used, as a low-loss and wide-band filter that can be used in frequency standards in which multiple bands and multiple modes are supported, in communication equipment, such as mobile phones, for example.

While example embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An N-path filter comprising:
a first input-output terminal and a second input-output terminal; and
an N number of signal paths, where N is an integer of three or more, connected in parallel with one another between the first input-output terminal and the second input-output terminal; wherein
each of the N number of signal paths includes:
a first modulator connected to the first input-output terminal and configured to modulate an input signal input from the first input-output terminal or the second input-output terminal;
a second modulator connected to the second input-output terminal and configured to modulate the input signal with a same phase as the first modulator; and
a base filter connected between the first modulator and the second modulator;
the first modulator and the second modulator are configured to modulate the input signal with a phase that is one of phases of the N number of signal paths defining one period and is different for each of the signal paths; and
the base filter is a low pass filter including an inductor.

2. The N-path filter according to claim 1, wherein
the base filter is a low pass filter including an inductor and a capacitor; and
of circuit elements included in the base filter, a circuit element connected closest to at least one of the first switch and the second switch is a capacitor connected between a path connecting the first input-output terminal and the second input-output terminal and a ground.

3. The N-path filter according to claim 1, wherein
the first modulator is a first switch configured to switch between connection and disconnection between the first input-output terminal and the base filter in accordance with a drive signal; and
the second modulator is a second switch configured to switch between connection and disconnection between the second input-output terminal and the base filter at a same time as the first switch in accordance with the drive signal.

4. The N-path filter according to claim 3, wherein
each of the first switch and the second switch includes a semiconductor element; and
of circuit elements included in the base filter, a circuit element connected closest to at least one of the first switch and the second switch is a capacitor connected between a path connecting the first input-output terminal and the second input-output terminal and a ground.

5. The N-path filter according to claim 1, wherein the base filter is defined by only a passive element.

6. The N-path filter according to claim 1, wherein, when a terminal impedance of the N-path filter is Z₀ and an input-output impedance of the base filter is Zb, a relationship of (Zb−N×Z₀)/(Zb+N×Z₀)<0.316 is satisfied.

7. The N-path filter according to claim 6, wherein the base filter is a low pass filter including an inductor and a capacitor.

8. The N-path filter according to claim 1, wherein a band width ratio of the N-path filter is more than about 0.1%.

9. The N-path filter according to claim 2, wherein
the inductor has an inductance value of about 1.03 pH;
the capacitor has a capacitance value of about 7.96 pF; and
the capacitor connected between the path connecting the first input-output terminal and the second input-output terminal and the ground has a capacitance value of about 2.46 pF.
